(19) United States
(12) Patent Application Publication
(10) Pub. No.: US 2023/0327050 A1
(43) Pub. Date: Oct. 12, 2023

(54) FLIP CHIP MICRODEVICE STRUCTURE

(71) Applicant: VueReal Inc., Waterloo (CA)

(72) Inventors: Gholamreza CHAJI, Waterloo (CA); Ehsanollah FATHI, Waterloo (CA); Hossein Zamani SIBONI, Waterloo (CA)

(73) Assignee: VueReal Inc., Waterloo, ON (CA)

(21) Appl. No.: 18/043,252

(22) PCT Filed: Sep. 2, 2021
(86) PCT No.: PCT/CA2021/051217

§ 371 Date: Feb. 27, 2023

Related U.S. Application Data
(60) Provisional application No. 63/133,982, filed on Jan. 5, 2021.
(60) Provisional application No. 63/110,535, filed on Nov. 6, 2020.
(60) Provisional application No. 63/073,552, filed on Sep. 2, 2020.

(51) Int. Cl. H01L 33/38; H01L 33/40

(52) U.S. Cl. CPC H01L 33/382; H01L 33/405

(57) ABSTRACT

What is disclosed is various aspects of the structure of flip chip or lateral micro devices having protection of connections. The various aspects comprise a structural combination of functional layers such as doped or blocking layers or quantum well structure, as well as dielectric layers, VIA's, optical enhancements layers, connection pads, protective layers, masks and additional layers. In addition, methods of fabrication of microdevices have also been disclosed where in patterning has been used. The present disclosure further relates to integrating vertical microdevices into a system substrate. The system substrate can have a backplane circuit as well. The integration covers the microdevices with dielectrics and couples the backplane through a VIA.

### FIELD OF THE INVENTION

The present disclosure relates to the structure and fabrication of flip chip or lateral micro devices into system substrate. The present disclosure further relates to integrating vertical microdevices into a substrate.

### BRIEF SUMMARY

According to one of the embodiments, there is a microdevice structure comprising, an etched part of the layers, a top doped layer and an active layer, at an edge of the microdevice, a dielectric layer formed covering aside wall exposed due to the etching of the layers, an ohmic layer formed on the doped layer to enhance the coupling to the doped layers, and an electrode connecting a bottom doped layer to a top surface.

According to another embodiment, there is a method to fabricate a microdevice with an etched edge, forming a hard mask on top of ohmic layers, patterning the hard mask to the shape of a complete microdevice at the top, adding an etched edge to a microdevice surface, etching layers to a thickness difference between a final height of the microdevice and an etched height of the edge, repatterning the hard mask to remove an area associated with the etched edge, and etching the layers again to make a re-etched height equal to a height of the layers on top of the bottom doped layer.

According to to another embodiment, there is a method to fabricate a microdevice with an etched edge, the method comprising, forming a first hard mask on a top surface, patterning the hard mask to a shape of a complete microdevice at the top including the part associated with the edge; performing a first etching process to etch layers to a thickness of an edge mesa, forming a second mask that covers the edge part of the microdevice, and performing the second etching process to etch the layers again to make a re-etched height equal to a height of the layers on top of a bottom doped layer.

According to another embodiment, there is a microdevice structure comprising, a stack of bottom doped layer, active layers and a top doped layer, blocking layers formed on a top of the microdevice, a dielectric layer covering part of a microdevice sidewall and a top surface of the microdevice such that a part of a bottom doped layer on the microdevice sidewall is exposed, an ohmic layer formed at least on the bottom doped layer, an electrode formed coupled to the bottom doped layer and also covering part of the top surface of the microdevice, a pad formed on the top surface coupling the electrode, a second electrode formed connecting the ohmic layer or top doped layer, and a second pad formed to couple the second electrode.

The present invention relates to a method to integrate vertical microdevices into a system substrate the method comprising, covering a sidewall of a microdevice with a first dielectric, covering a top surface of microdevice with a second dielectric, and creating a first VIA opening on the second dielectrics. The bottom side of the microdevice may be covered by a third dielectric and a second VIA opening is created in the third dielectric.

### BRIEF DESCRIPTION OF THE DRAWINGS

The foregoing and other advantages of the disclosure will become apparent upon reading the following detailed description and upon reference to the drawings.

FIG. 1A shows a microdevice structure with a functional structure.

FIG. 1B shows a Variation of the microdevice structure with a functional structure in FIG. 1A.

FIG. 1C shows a layer extended over the sidewalls of the functional structure.

FIG. 2A shows a flip-chip structure where a part of the layers at the edge of the microdevice is etched.

FIG. 2B shows one variation of etching the edge.

FIG. 2C shows the top view of the etched devices.

FIG. 2D shows the etching area of two adjacent devices on two opposite corners.

FIG. 2E shows a system substrate example where the pads on the system substrate are switched for some pixels to match the orientation of the new micro-devices.

FIG. 3A shows a structure where the coupling to the bottom doped layer is done through a sidewall.

FIG. 3B shows a structure where the coupling to the bottom doped layer is done through a sidewall.

FIG. 4 shows an embodiment that simplifies the integration of vertical microdevices into the system substrate.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

In this description, the term “device” and “microdevice” are used interchangeably. However, it is clear to one skilled in the art that the embodiments described here are independent of the device size.

To develop a system (display, sensors or other), microdevices are integrated into a system substrate.

A few embodiments of this description are related to integration of micro-devices into a receiving substrate. The system substrate may comprise micro light emitting diodes (LEDs), Organic LEDs, sensors, solid state devices, integrated circuits, (micro-electro-mechanical systems) MEMS, and/or other electronic components.

The receiving substrate may be, but is not limited to, a printed circuit board (PCB), thin film transistor backplane, integrated circuit substrate, or, in one case of optical micro devices such as LEDs, a component of a display, for example a driving circuitry backplane. The patterning of micro device donor substrate and receiving substrate can be used in combination with different transfer technology including but not limited to pick and place with different mechanisms (e.g. electrostatic transfer head, elastomer transfer head), or direct transfer mechanism such as dual function pads and more).

Microdevices can have a bottom and top side. The bottom has a doped layer followed by active layers and another doped layer different from the bottom doped layer on the top. There can be other layers such as blocking layers around the active layers. The active layers creat emission or absorb a wave and create a charge. Conductive layers are formed to provide access to the doped layers. As the two doped layers are on two different sides of the device, one method to access two the layers is to couple two pads on one surface of the device (e.g. top) to both doped layers. The invention cited here provides coupling pass to the bottom side of the doped layer while minimizing the impact on the device structure and enabling smaller devices.

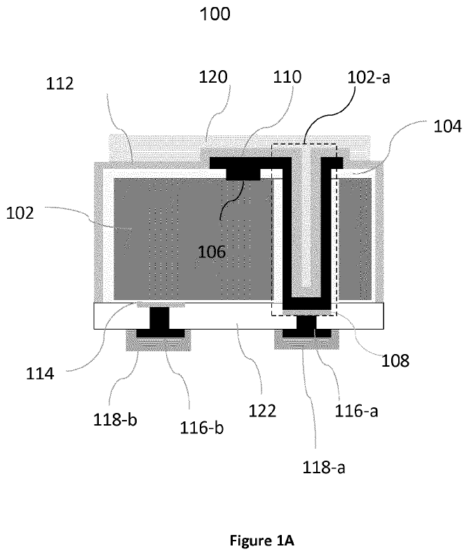

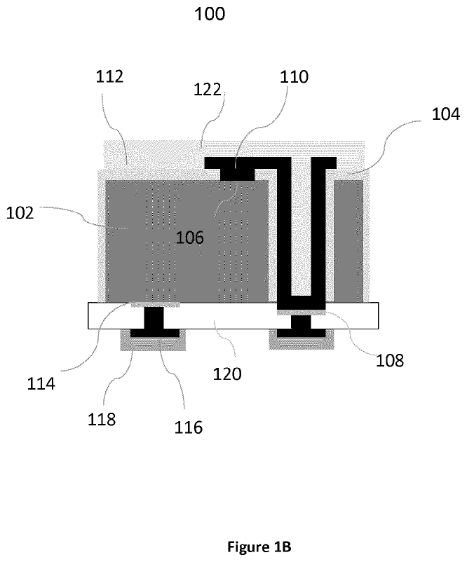

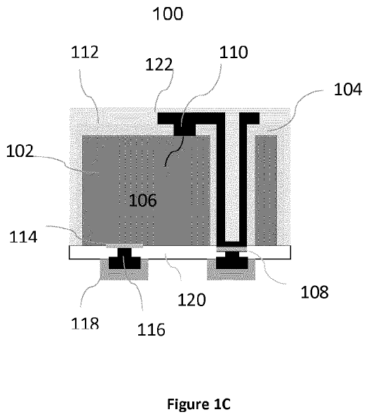

With reference to FIG. 1A, a microdevice structure 100 is presented. Here, functional structure 102 may comprise different layers such as doped, blocking layers, quantum well structure, and other types of layers. A VIA 102-a is formed in the functional structure 102 enabling it to couple to the top or bottom side of the functional structure 102 from the opposite side. A dielectric layer 104 covering the sidewall of the VIA. The layer 104 can also cover part or all of the surfaces of the functional structure 102. A conductive layer 110 is filling the VIA 102-a partially and is coupled to the top surface of the device structure 104 through an opening 106 in the dielectric layer 104 (the same effect can be done for the bottom surface of the structure 102). If the dielectric layer 104 does not cover the surface of the device, the opening 106 is not needed.

Another layer 112 can cover the surface of the microdevice 100. This layer 112 can be an optical enhancement layer to enable light extraction from the microdevice. The top surface of the microdevice and the VIA structure is then filled with a layer 120. This layer 120 enhances the structure integrity of the device or it can also act as an optical enhancement layer. The layer can be polymer such as polyamide, BCB, or SOG or other types.

At the bottom side of the functional structure 102, there is a protective layer 108 protecting the layer 110 from any post processing such as etching or patterning. The layer 110 can be reflective layers such as Al or Silver that are very sensitive to different process steps such as etching. The layer 108 can be Ni, Cr. or Au that are more resistant to different processes. Another layer 114 can form on the bottom surface of the device. This can be ohmic or protective layer 114. A dielectric layer 122 covers at least the VIA and part of the bottom surface of the device. Pads 118-a and 118-b are coupled to the layers 108 and 114 through VIA 116-a and 116b. The VIA's 116-a and 116-b can be filled with the pads material or different material.

In another related case demonstrated in FIG. 1B, the layers 112 and 120 are combined.

In another related case demonstrated in FIG. 1C, the layer 122 is extended over the sidewalls of the structure 102.

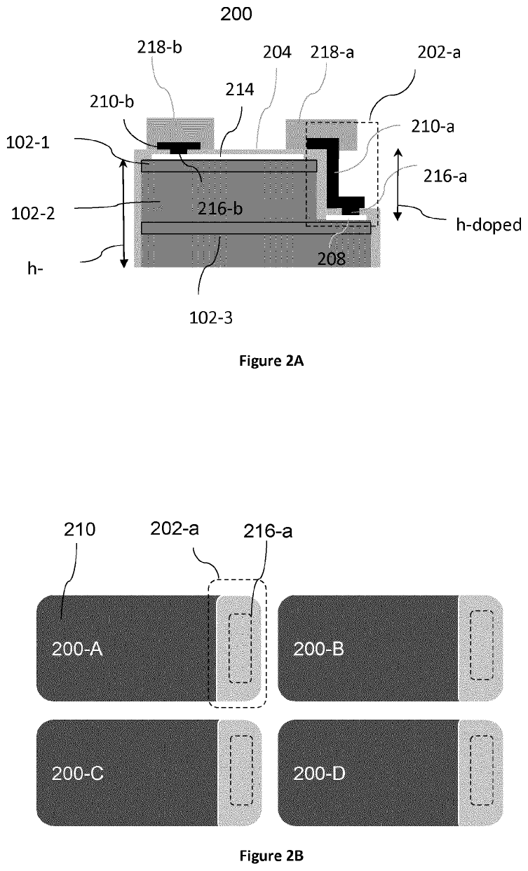

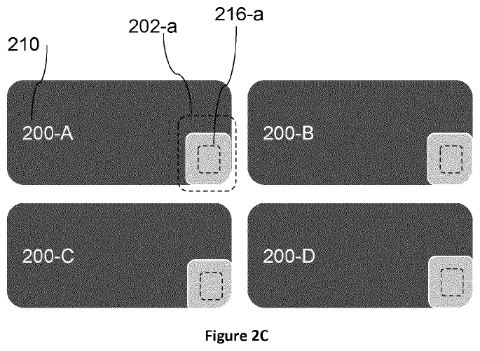

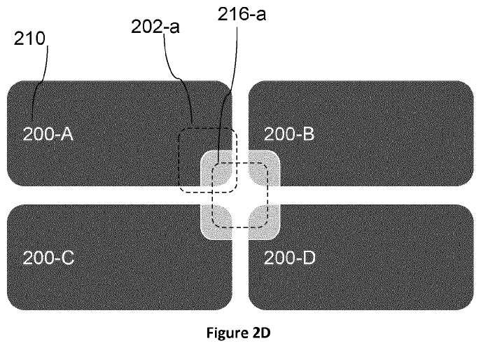

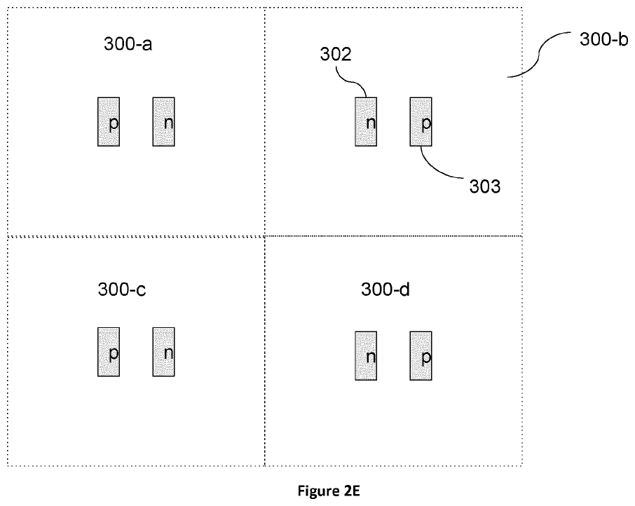

FIG. 2A shows a flip-chip structure where a part of the layers (top doped layer 102-1 and active layer 102-2) at the edge of the microdevice 202-a is etched to get access to the bottom doped layer 102-3 at the bottom side of the device. A dielectric layer 204 is formed to cover the side wall exposed due to the etching of the layers. An ohmic layer 208 may be formed on the doped layer to enhance the coupling to the doped layer. An electrode 210-a brings the access to the bottom doped layer to the top surface while the dielectric layer 204 prevents the short between the other layers and the electrode 210-1. The dielectric layer 204 can be deposited using ALD, PECVD or other methods and it can be different material (e.g. Al2O3, SiN, SiO2, . . . ) depending on the microdevice layers. The electrode can be reflective or transparent. In case of reflective electrodes, it can cover the entire etched area to reflect the light toward the bottom surface of the device. The ohmic layer 208 and electrode 210-a can be the same layers. Another dielectric layer can cover the electrode. Pads 218-a can be formed for enhancing the integration of the microdevice into a system substrate. Another electrode 210-b, ohmic layer 214 or bump 218-b are coupled to the top doped layers.

One way to fabricate the microdevices with the etched edge is as follows. A hard mask is formed on top of the layers (here the ohmic layer 214 for the top dopant can be already formed). The mask is patterned to the shape of the complete device at the top view (here the etched edge is also added to the device surface). The layers 102-1, 102-2, and 102-3 are etched to the thickness that is the difference between the final height (h-total) of the device and the etch height (h-doped) of the edge 202-a. After this step, the hard mask is repatterned to remove the area associated with the etched edge 202-a. Again the layers 102-1, 102-2, and 102-3 are etched. This etching height is equal to the height (h-doped) of the etched corner 202-a. Therefore the edge 202-a will be etched to the bottom doped layer and at the same time the rest of the area will be etched to the total height (h-total−h-doped+h-doped=h-total). After this stage, one can treat the structure, and form the dielectric layer 204. The VIA's 216-a, and 216-b are formed to provide access to the doped layers 102-1, and 102-2 (or ohmic layers 214 and 208). The electrodes 210-a and 210-b are deposited and formed. And finally, pads 218-a and 2018-b can be fabricated on top of the electrodes 210-a and 210-b and top surface of the device.

Another related embodiment to fabricate the microdevices with the etched edge is as follows. A hard mask is formed on top of the layers (here the ohmic layer 214 for the top dopant can be already formed). The mask is patterned to the shape of the complete device at the top view including removing the part associated with the edge 202-a. The layers 102-1, 102-2, and 102-3 are etched to the thickness of the etch height (h-doped) of the edge 202-a. Here, one can treat the device and passivate it prior to the next etching step. It is possible to remove the hard mask and add a new mask that covers the edge. However, it will make the device large by the misalignment. In another related embodiment, a second hard mask is added to the previous hard mask to cover off the edge part. As this etching step can be shorter the hard mask can be from softer material such as photoresist. This hard mask can be a photo definable polymer or typical photoresist, metal, dielectric or other materials. The mask can cover part of the previous hard mask to make sure there is no gap between the two masks. The structure is etched to the difference of total height (h-total) and doped height (h-doped). The hard masks can be removed prior or after treatment. After this stage, one can treat the structure, and form the dielectric layer 204. The VIA's 216-a, and 216-b are formed to provide access to the doped layers 102-1, and 102-2 (or ohmic layers 214 and 208). The electrodes 210-a and 210-b are deposited and formed. And finally, pads 218-a and 2018-b can be fabricated on top of the electrodes 210-a and 210-b and top surface of the device.

FIG. 2B shows one variation of etching the edge 202-a. Here, the device size is limited by the width of the etching edge 202-a and the VIA 216-a in the dielectric layer 204.

Another variation of the etching of the edge 202-a is demonstrated in FIG. 2C (top view of the device). Here, one corner of the devices 200-A, 200-B, 200-C and 200-D are etched to provide access to the bottom doped layer. This can improve the device size by reducing the area allocated to the etching (202-a) and VIA 216-a. However, the spacing between the device and the space between the VIA and edge is still impacting the device pitch and size.

Another variation of the device is demonstrated in FIG. 2D. Here, at least the etching area of two adjacent devices are on two opposite corners. As a result, the etching area 202-a for the adjacent devices (200-A, 200-B, 200-C and 200-D) facing each other. This in turn allows us to reduce the spacing between the devices or eliminate the space we need between VIA 216-a and the edge of the device. Furthermore, the electrodes described in FIG. 2A can be first shared between adjacent devices to make measuring the devices easier. After that the electrodes can be singulated for each device.

To match the new device orientations, either system substrate design needs to be modified or the microdevice orientation needs to be fixed before transferring to the system substrate. FIG. 2E shows a system substrate example where the pads on the system substrate are switched for some pixels to match the orientation of the new microdevices. In one example, the pixels 300-a, 300-b, 300-c, 300-d include at least microdevice pads 302, and 303. In one case, to match the orientation of microdevices in the donor substrate, the microdevices in alternating columns have the pads switched in the system substrate. For example, pixels 300-a and 300-c, the pads coupling to the top pad of the microdevice (p) 302 are on the left and the pad coupling to the bottom pad of the microdevice (n) 303 are on the right. At the same time, the pixels 300-b and 300-d, the pads coupling to the top pad of the microdevice (p) 302 are on the right and the pad coupling to the bottom pad of the microdevice (n) 303 are on the left.

In another case, the process of transferring will be followed as a) checking the microdevice orientation, b) if the device orientation does not match the system substrate pads, adjust the device orientation by rotating the device, and c) transfer the device into the system substrate.

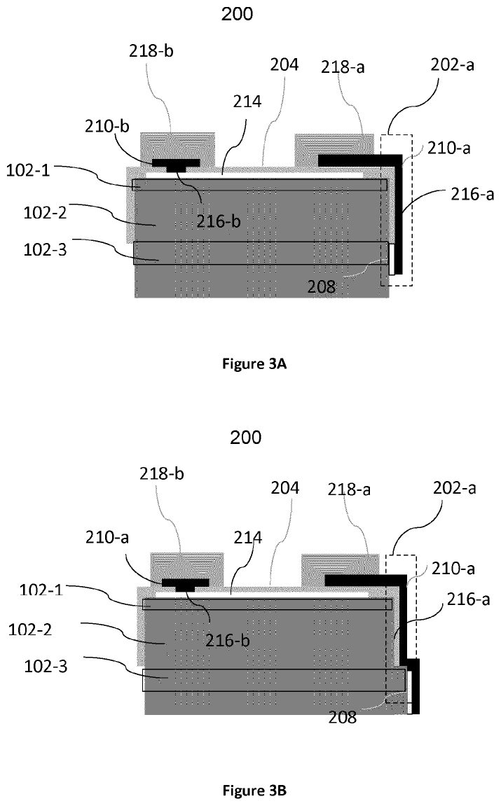

FIGS. 3A and 3B show a structure where the coupling to the bottom doped layer is done through sidewall. Here, the microdevice is a stack of bottom doped layer 102-3, active layers 102-2 and top doped layer 102-1. There can be other layers such as blocking layers. An ohmic layer 214 is formed on top of the microdevice to enhance the coupling to the top doped layer. A dielectric layer covering part of the microdevice sidewall and top surface of the microdevice. The dielectric exposes part of the bottom doped layer on the sidewall. It is very important that the dielectric cover the sidewall from the top surface and overlap with the bottom doped layer to make sure the electrode does not short to the other layers. Here an ohmic layer 208 is formed at least on the bottom doped layer 102-3. An electrode 210-a is formed to provide access to the bottom doped layer 102-3. The electrode also covers part of the top surface. A pad 218-a is formed on the top surface coupling 202-a the electrode 210-a. Another electrode 210-b is formed to provide access to the ohmic layer or top surface doped layer 102-1. A pad is formed to couple to that electrode 210-b.

In one case, a dielectric layer is formed on the top surface (it can be patterned to the same shape as the microdevice and a protection layer can be on top of the dielectric). A hard mask is formed on the top layers. The hard mask is patterned to the shape of the device. The layers are etched to pass part of the bottom doped layer 102-3. At this point, treatment can be done and a dielectric layer is formed to cover the exposed sidewall of the device. The remaining hard mask is removed (in one case the first direlectric and the hard masks are the same layer. In this case, the hard mask is not removed after etching). After these steps, ohmic layer 208 and electrode 202-a are formed.

In one case, the sidewall that is providing access to the bottom doped layer is extended from the side of the microdvice as shown in FIG. 3B. This structure can be developed by the process of wet etching. After the first etching of the layers (getting to the bottom doped layer), a wet etching process can be used to etch the layers inwardly. After the second etching steps, using the original mask, the doped layer 102-3 will be extended outward.

### Embodiments of FIGS. 2 and 3

According to one of the embodiments, there is a microdevice structure comprising, an etched part of the layers, a top doped layer and an active layer, at an edge of the microdevice, a dielectric layer formed covering aside wall exposed due to the etching of the layers, an ohmic layer formed on the doped layer to enhance the coupling to the doped layers, and an electrode connecting a bottom doped layer to a top surface. The structure further has a dielectric layer deposited using ALD, PECVD or other methods wherein the dielectric layer can be made of Al2O3, SiN, or SiO2, and also wherein the electrode can be reflective or transparent. Here the reflective electrode may cover the entire etched area to reflect a light toward the bottom surface of the microdevice. The structure may further have the ohmic layer and electrode as the same layers. The structure may further have a second dielectric layer covering the electrode. The structure may further have a pad formed over the second electrode. The structure may further have a second electrode, a second ohmic layer or bump (a pad) are coupled to the top doped layers. The structure may further have the microdevice size limited by a width of an etching edge and a VIA in the dielectric layer. The structure may further have one corner of the micro device etched to provide access to the bottom doped layer. The structure may further have the etched area of two adjacent microdevices on two opposite corners such that the etching areas for the adjacent microdevice devices face each other. The structure may further have the electrodes described are at first shared between the adjacent microdevices for measurement and at second the electrodes are singulated for each microdevice.

According to another embodiment, there is a method to fabricate a microdevice with an etched edge, forming a hard mask on top of ohmic layers, patterning the hard mask to the shape of a complete microdevice at the top, adding an etched edge to a microdevice surface, etching layers to a thickness difference between a final height of the microdevice and an etched height of the edge, repatterning the hard mask to remove an area associated with the etched edge, and etching the layers again to make a re-etched height equal to a height of the layers on top of the bottom doped layer. The method further comprises, the edge etched to the bottom doped layer and a rest of an area etched to the total height. The method further comprises, wherein the dielectric layer is formed over the ohmic layer and parts of the sidewall. The method further comprises, wherein a VIA's are formed to provide access to the doped layers or ohmic layers and electrodes are deposited and formed. The method further comprises, wherein pads are fabricated on top of the electrodes and a top surface of the microdevice.

According to another embodiment, there is a microdevice structure comprising, a stack of bottom doped layer, active layers and a top doped layer, blocking layers formed on a top of the microdevice, a dielectric layer covering part of a microdevice sidewall and a top surface of the microdevice such that a part of a bottom doped layer on the microdevice sidewall is exposed, an ohmic layer formed at least on the bottom doped layer, an electrode formed coupled to the bottom doped layer and also covering part of the top surface of the microdevice, a pad formed on the top surface coupling the electrode, a second electrode formed connecting the ohmic layer or top doped layer, and a second pad formed to couple the second electrode. The structure may further have a dielectric layer formed on the top surface. Here a hard mask is formed on the top layer. Here further the hard mask is patterned to the shape of the microdevice. Here further, at least an ohmic layer is etched to pass part of the bottom doped layer. Here further, a dielectric layer is formed to cover the exposed sidewall of the microdevice. Here further, a remaining hard mask is removed. Here further, another ohmic layer and a second electrode are formed.

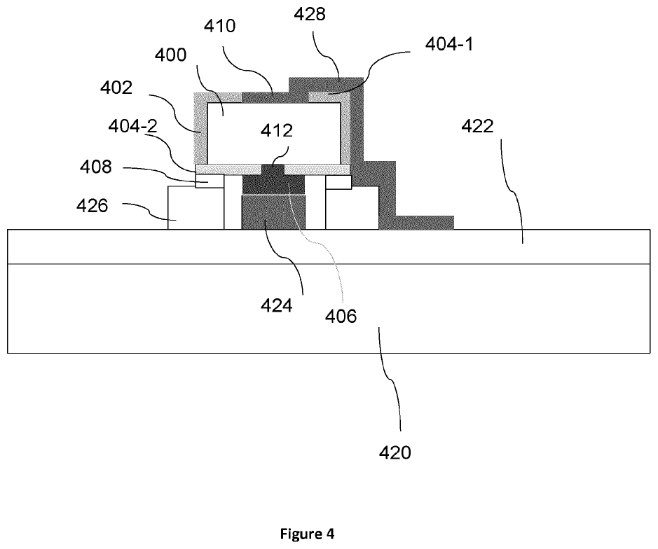

### Embodiments of FIG. 4

Microdevices can be microLED or sensors or MEMS or OLEDs or etc. A system substrate consists of a substrate and a backplane circuitry which controls the microdevices by biasing the micro-devices.

The microdevices can be in different forms such as vertical where at least one contact is at the top and one contact is at the bottom surface of the device.

The challenge with vertical microdevice integration into system substrate is the post processing to create contact to the top layer.

FIG. 4 shows an embodiment that simplifies the integration of vertical microdevices into the system substrate. Microdevice 400 can have a dielectric 402 covering the sidewall. Another dielectric 404-1 covering the top surface of the device 400. And there can be another dielectric 404-2 covering the bottom surface of the device 400. The dielectrics 404-1, 404-2, and 402 can be the same layers or different. There is a VIA opening 410 on the top dielectric 404-1. If there is a dielectric 404-2 on the bottom surface of the device, there is a VIA opening 412 in that dielectric 404-2. The dielectric layers can be developed using ALD (Atomic layer deposition), PECVD (Plasma-enhanced chemical vapor deposition), sputtering or other methods. The material used for the dielectric can be organic such as polyamide, BCB(Benzocyclobutene), or inorganic such as SiN, SiO2, etc.

A pad 406 is formed on the bottom surface of the device 400. A dielectric shell 408 can be developed which is surrounding the pads. The dielectric shell 408 can be adhesive.

The system substrate 420 can have backplane circuit 422 on the top surface of the backplane. The backplane circuitry can be coupled to a second pad 424. A second shell 426 is formed to surround the pad 424. The second shell 426 can be adhesive. At least one dimension associated with the area of the shell 426 is larger than the one dimension of the microdevice 400.

The pad 406 of the microdevice 400 is coupled to the pad 424 of the system substrate 120. During the bonding process to couple the pads, the shields 406 and 424 are also bonded protecting the pads such that shields are also bonded to encapsulate the coupled bonds. After this process an electrode 428 can form on top of the device 400 to couple the top side through VIA 410 to the backplane 422. The electrode can be transparent, reflector or opaque.

In one case, it can be patterned in rows or columns. In another related case, it can form a common electrode for a set of microdevices on the system substrate.

The shield can be only on system substrate or microdevice or both. There can be a gap between the pads and shield. In another case, the shield and the pads are connected physically. The combined height of the shields can be the same as the combined height of the pads. If the combined height of either pad or shield is higher than that of the other one, the taller structure needs to be deformed during the bonding to provide coupling of the other structure.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

1. A microdevice structure comprising:
an etched part of the layers, a top doped layer, and an active layer, at an edge of the microdevice;
a dielectric layer formed covering aside wall exposed due to the etching of the layers;
an ohmic layer formed on the doped layer to enhance the coupling to the doped layers; and
an electrode connecting a bottom doped layer to a top surface.

2. The structure of claim 1, wherein dielectric layer is deposited using ALD, PECVD or other methods.

3. The structure of claim 2, wherein the dielectric layer is made of Al2O3, SiN, or SiO2.

4. The structure of claim 1, wherein the electrode is reflective or transparent.

5. The structure of claim 4, wherein the reflective electrode covers the entire etched area to reflect a light toward a bottom surface of the microdevice.

6. The structure of claim 1, wherein the ohmic layer and electrode are the same layers.

7. The structure of claim 1, wherein a second dielectric layer covers the electrode.

8. The structure of claim 1, wherein a pad is formed over the second electrode.

9. The structure of claim 1, wherein a second electrode, a second ohmic layer, or a bump (a pad) are coupled to the top doped layers.

10. The structure of claim 1, wherein a microdevice size is limited by a width of an etching edge and a VIA in the dielectric layer.

11. The structure of claim 1, wherein one corner of the micro device is etched to provide access to the bottom doped layer.

12. The structure of claim 1, wherein the etching area of two adjacent microdevices are on two opposite corners such that the etching areas for the adjacent microdevice devices face each other.

13. The structure of claim 1, wherein the electrodes are at first shared between the adjacent microdevices for measurement and at second the electrodes are singulated for each microdevice.

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. (canceled)

54. (canceled)

55. (canceled)

56. (canceled)

57. (canceled)

58. (canceled)

59. (canceled)

60. (canceled)

61. (canceled)

62. (canceled)

63. (canceled)

64. (canceled)

65. (canceled)

66. (canceled)

67. (canceled)

68. (canceled)

69. (canceled)

70. (canceled)
